(19) United States
(12) Patent Application Publication
(10) Pub. No.: US 2012/0145244 A1
(43) Pub. Date: Jun. 14, 2012

(54) PHOTORECEPTIVE LAYER INCLUDING HETEROGENEOUS DYES AND SOLAR CELL EMPLOYING THE SAME

(76) Inventors: Won-cheol Jung, Yongin-si (KR); Kyung-sang Cho, Yongin-si (KR); Jung-gyu Nam, Yongin-si (KR); Sang-cheol Park, Yongin-si (KR)

(21) Appl. No.: 13/403,406

(22) Filed: Feb. 23, 2012

Related U.S. Application Data
(63) Continuation of application No. 11/271,928, filed on Nov. 14, 2005.

(30) Foreign Application Priority Data
Jan. 22, 2005 (KR) 10-2005-0006083

(51) Int. Cl. H01L 31/0216; B05D 5/06; C09D 7/12

(52) U.S. Cl. 136/263; 106/287.19; 427/76

(57) ABSTRACT

A photoreceptive layer including heterogeneous dyes is provided. The dye fill density is enhanced and light absorption is achieved at a broad wavelength range, which enables the beneficial utilization of the photoreceptive layer in a dye-sensitized solar cell.

### CROSS-REFERENCE TO RELATED PATENT APPLICATION

This application is a continuation of application Ser. No. 11/271,928 filed Nov. 14, 2005, which claimed priority from Korean Patent Application No. 10-2005-0006083, filed on Jan. 22, 2005, in the Korean Intellectual Property Office, the disclosures of which are incorporated herein in its entirety by reference.

### BACKGROUND OF THE DISCLOSURE

1. Field of the Disclosure

The present disclosure relates to a photoreceptive layer including heterogeneous dyes and a solar cell including the same. More particularly, the present invention relates to a photoreceptive layer which can enhance an energy conversion efficiency by using heterogeneous dye molecules with different absorption wavelength ranges, and a solar cell including the same.

2. Description of the Related Art

To provide solutions to pending energy problems, various studies to find alternatives to fossil fuels have been conducted. In particular, studies involving applications of natural energy sources such as wind power, nuclear power, or solar power to replace petroleum that is expected to be depleted within several tens years have been widely pursued. Among these natural energy sources, solar energy used for solar cells is an unlimited and environmental-friendly energy source, unlike the other energy sources. Thus, selenium (Se) solar cells were first developed in 1983. Since then, silicon solar cells have received much interest.

However, silicon solar cells have not been widely applied due to high manufacturing costs. Also, many difficulties are involved with respect to the energy efficiency enhancement of the silicon solar cells. In view of these problems, much interest has been focused on the development of dye-sensitized solar cells having low manufacturing costs.

Unlike silicon solar cells, dye-sensitized solar cells are photoelectrochemical solar cells primarily using a photosensitive dye molecule capable of generating electron-hole pairs by absorbing visible light and a transition metal oxide transporting of the generated electrons to a semiconductor electrode. Graetzel cells reported by Graetzel et al. from Switzerland in 1991 are representative of commonly known dye-sensitized solar cells. The Graetzel cells offer lower manufacturing costs (per power) than conventional silicon solar cells and thus have received much interest as promising substitutes for conventional solar cells.

Referring to FIG. 1, a dye-sensitized solar cell includes a conductive transparent substrate 11, a photoreceptive layer 12, an electrolyte layer 13, and an opposite electrode 14. The photoreceptive layer 12 includes metal oxide 12a and a dye 12b. The dye 12b is excited by absorbing light transmitted through the conductive transparent substrate 11. Generally, it is known that a complex such as a ruthenium pigment is used as the dye 12b. However, such a single type of dye cannot absorb light over a broad wavelength range. In particular, there arises a problem in that light absorptivity at a near-infrared wavelength range of above 850 nm is poor.

### SUMMARY OF THE DISCLOSURE

The present invention may provide a photoreceptive layer including heterogeneous dyes with different absorption wavelength ranges.

The present invention also may provide a dye-sensitized solar cell including the photoreceptive layer.

According to an aspect of the present invention, there is provided a photoreceptive layer including: a metal oxide; a first dye formed on a surface of the metal oxide; and a second dye formed on another surface of the metal oxide via a compound represented by formula 1 below:

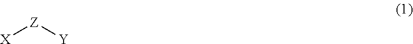

wherein X is a functional group binding with the metal oxide;

Y is a functional group binding with the second dye; and

Z is a bond, a substituted or unsubstituted alkylene group of 1-30 carbon atoms, a substituted or unsubstituted alkenylene group of 2-30 carbon atoms, a substituted or unsubstituted heteroalkylene group of 1-30 carbon atoms, a substituted or unsubstituted heteroalkenylene group of 2-30 carbon atoms, a substituted or unsubstituted arylene group of 6-30 carbon atoms, a substituted or unsubstituted heteroarylene group of 3-30 carbon atoms, or a substituted or unsubstituted arylalkylene group of 6-30 carbon atoms.

X and Y may be each independently —COOR, —OCOR, —COSR, —SCOR, —NRR′, —OR, or —OSR where R and R′ are each independently a hydrogen atom, a halogen atom, a cyanide group, a nitro group, a substituted or unsubstituted alkyl group of 1-10 carbon atoms, a substituted or unsubstituted alkenyl group of 2-10 carbon atoms, a substituted or unsubstituted alkoxy group of 1-10 carbon atoms, a substituted or unsubstituted aryl group of 6-20 carbon atoms, a substituted or unsubstituted heteroaryl group of 6-20 carbon atoms, a substituted or unsubstituted aryloxy group of 6-20 carbon atoms, or a substituted or unsubstituted heteroaryloxy group of 6-20 carbon atoms.

The first dye may be a ruthenium complex, a xanthine dye, a cyanine dye, phenosafranine, cabri blue, thiosine, a basic dye such methylene blue, a porphyrin compound such as chlorophyll, zinc porphyrin, and magnesium porphyrin, an azo dye, a phthalocyanine compound, a ruthenium trisbipyridyl complex, an anthraquinone dye, a polycyclic quinone dye, or a mixture thereof.

The second dye may be a quantum dot compound.

According to another aspect of the present invention, there is provided a dye-sensitized solar cell including the photoreceptive layer.

### BRIEF DESCRIPTION OF THE DRAWINGS

The above and other features and advantages of the present invention are apparent by describing in detail exemplary embodiments thereof with reference to the attached drawing in which:

FIG. 1 is a schematic view illustrating a dye-sensitized solar cell according to the present invention.

### DETAILED DESCRIPTION OF EXEMPLARY EMBODIMENTS

The present invention will now be described more fully with reference to the accompanying drawing, in which an exemplary embodiment of the invention is shown.

A photoreceptive layer according to the present invention includes metal oxide and different types of dyes, unlike a conventional photoreceptive layer including a single type of dye and thus absorbing light at a restricted wavelength range. Therefore, an absorption wavelength range can be broadened, thereby enhancing energy conversion efficiency.

Generally, a dye used in a photoreceptive layer is adsorbed to a surface of metal oxide to form a dye layer. However, since the dye layer has a discontinuous structure, the metal oxide has a dye-free surface area. In this respect, in the present invention, a compound with a predetermined structure is bound to the dye-free surface area of metal oxide, and a heterogeneous dye, i.e., a secondary dye with an absorption wavelength range different from the previously adsorbed dye, i.e., the primary dye is bound to an end of the compound.

The compound serving as a binding mediator between the metal oxide and the secondary dye may be a compound represented by formula 1 below:

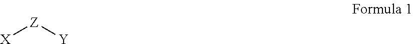

wherein X is a functional group binding with the metal oxide,

Y is a functional group binding with the secondary dye, and

Z is a bond, a substituted or unsubstituted alkylene group of 1-30 carbon atoms, a substituted or unsubstituted alkenylene group of 2-30 carbon atoms, a substituted or unsubstituted heteroalkylene group of 1-30 carbon atoms, a substituted or unsubstituted heteroalkenylene group of 2-30 carbon atoms, a substituted or unsubstituted arylene group of 6-30 carbon atoms, a substituted or unsubstituted heteroarylene group of 3-30 carbon atoms, or a substituted or unsubstituted arylalkylene group of 6-30 carbon atoms.

The compound of formula 1 has at least one end functional group capable of binding with the metal oxide and at least one end functional group capable of binding with the secondary dye. Preferably, the functional group capable of binding with the metal oxide is a hydrophilic group. More preferably, the compound of formula 1 is a selective self-assemblable compound since it must be bound to a primary dye-free surface area of the metal oxide. That is, in order for the compound of formula 1 to selectively bind with the metal oxide generally having a hydrophilic surface, it is necessary to appropriately select an end functional group of the compound of formula 1. In particular, to prevent a binding of the compound of formula 1 with the primary dye previously adsorbed to a surface of the metal oxide, appropriate selection of the end functional group of the compound of formula 1 is important.

After an end functional group of the compound of formula 1 is bound to a surface of the metal oxide, the other end functional group of the compound of formula 1 is bound to the secondary dye according to the present invention. In this case, the secondary dye is positioned away from the surface of the metal oxide due to the presence of the compound of formula 1, which increases the total fill density of the dyes. In addition, the use of the secondary dye with an absorption wavelength different from the primary dye increases the efficiency of a photoreceptive layer.

The functional group capable of selectively binding with the metal oxide and the functional group capable of binding with the secondary dye may be each independently —COOR, —OCOR, —COSR, —SCOR, —NRR′, —OR, or —OSR where R and R′ are each independently a hydrogen atom, a halogen atom, a cyanide group, a nitro group, a substituted or unsubstituted alkyl group of 1-10 carbon atoms, a substituted or unsubstituted alkenyl group of 2-10 carbon atoms, a substituted or unsubstituted alkoxy group of 1-10 carbon atoms, a substituted or unsubstituted aryl group of 6-20 carbon atoms, a substituted or unsubstituted heteroaryl group of 6-20 carbon atoms, a substituted or unsubstituted aryloxy group of 6-20 carbon atoms, or a substituted or unsubstituted heteroaryloxy group of 6-20 carbon atoms.

Illustrative examples of the compound of formula 1 having the above functional groups include compounds represented by formulae 2 through 9 below:

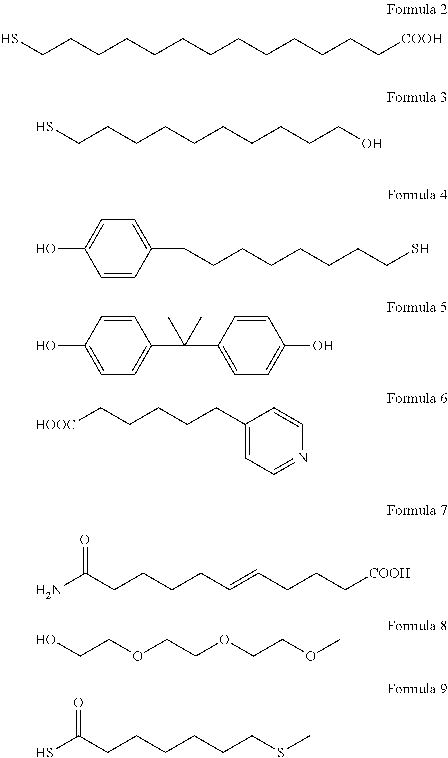

The above compounds except the compound represented by formula 5 have different functional groups on both ends thereof. An end functional group having high reactivity with a surface of metal oxide is preferentially bound to the surface of the metal oxide. The reactivity of the functional groups with metal oxide is determined by hydrophilicity, coordinate bond selectivity, etc. Generally, functional groups such as a carboxyl group and a hydroxyl group exhibit more enhanced reactivity with a surface of metal oxide, relative to a thiol group. However, binding selectivity of the functional groups with metal oxide may vary according to the type of a metal used for the secondary dye.

There are no limitations on the primary dye previously bound to metal oxide prior to binding of the metal oxide with the compound of formula 1 provided that the primary dye is commonly used in the solar cell industry or the photocell industry. A ruthenium complex is preferable. However, the primary dye is not particularly limited provided that it has a charge separation function and a sensitization function. For example, the primary dye may be a xanthine dye such as rhodamine B, rose bengal, eosin, and erythrosin; a cyanine dye such as quinocyanine and cryptocyanine; a basic dye such as phenosafranine, cabri blue, thiosine, and methylene blue; a porphyrin compound such as chlorophyll, zinc porphyrin, and magnesium porphyrin; an azo dye; a phthalocyanine compound; a complex compound such as ruthenium trisbipyridyl complex; an anthraquinone dye; or a polycyclic quinone dye. These dye compounds may be used alone or in combination. The ruthenium complex may be RuL₂(SCN)₂, RuL₂(H₂O)₂, RuL₃, RuL₂, or RuLL(SCN)₂ where L is 2,2′-bipyridyl-4,4′-dicarboxylate.

The secondary dye binding with metal oxide via the compound of formula 1 may be a common quantum dot compound, but is not limited thereto.

The quantum dot compound that can be used as the secondary dye may be a material selected from (a) a first element selected from Group II, XII, XIII, and XIV elements and a second element selected from Group XVI elements; (b) a first element selected from Group XIII elements and a second element selected from Group XV elements; and (c) a Group XIV element, or a core-shell structure compound thereof. Illustrative examples of the quantum dot compound include MgO, MgS, MgSe, MgTe, CaO, CaS, CaSe, CaTe, SrO, SrS, SrSe, SrTe, BaO, BaS, BaSe, BaTE, ZnO, ZnS, ZnSe, ZnTe, CdO, CdS, CdSe, CdTe, HgO, HgS, HgSe, HgTe, Al₂O₃, Al₂S₃, Al₂Se₃, Al₂Te₃, Ga₂O₃, Ga₂S₃, Ga₂Se₃, Ga₂Te₃, In₂O₃, In₂S₃, In₂Se₃, In₂Te₃, SiO₂, GeO₂, SnO₂, SnS, SnSe, SnTe, PbO, PbO₂, PbS, PbSe, PbTe, AlN, AlP, AlAs, AlSb, GaN, GaP, GaAs, GaSb, InN, InP, InAs, InSb, BP, Si, and Ge. Of course, the quantum dot compound may also be a core-shell structure compound composed of two or more selected from the above-illustrated examples.

The use of the secondary dye according to the present invention increases the total fill density of dyes, thereby increasing a fill factor. Furthermore, the adoption of the secondary dye in solar cells increases a photoelectric conversion efficiency.

The metal oxide contained in the photoreceptive layer according to the present invention may be semiconductor nanoparticles derived from a compound semiconductor or a perovskite structure compound, in addition to a single semiconductor such as silicon. Preferably, the metal oxide is n-type semiconductor nanoparticles in which conduction-band electrons serve as carriers for supplying anode current upon light excitation. For example, the metal oxide may be TiO₂, SnO₂, ZnO, WO₃, Nb₂O₅, or TiSrO₃. Anatase-type TiO₂ is particularly preferable. However, the metal oxide is not limited to the above-illustrated examples. The above metal oxide semiconductors may be used alone or in combination of two or more. It is preferable that the semiconductor nanoparticles have a large surface area so that dyes adsorbed onto the surfaces of the semiconductor nanoparticles can absorb much light. In this regard, it is preferable to adjust the particle size of the semiconductor nanoparticles to 20 nm or less, more preferably approximately 5 to 20 nm.

A representative method of forming a photoreceptive layer according to the present invention will now be described in detail.

Initially, a first dye is adsorbed onto a surface of metal oxide. Then, a dispersion solution of a compound of formula 1 in a solvent is sprayed on the first dye-adsorbed metal oxide or the first dye-adsorbed metal oxide is dipped in the dispersion solution, followed by washing and drying. Then, the resultant metal oxide is coated with or dipped in a second dye-containing solution, followed by washing and drying, to thereby form a photoreceptive layer according to the present invention. It is preferable to form the photoreceptive layer on a conductive transparent substrate previously coated with the metal oxide.

The solvent for dispersing the compound of formula 1 is not particularly limited but may be acetonitrile, dichloromethane, methoxyacetonitrile, ethanol, etc.

After coating the metal oxide with the dispersion solution containing the compound of formula 1, the resultant structure may be washed with a solvent to form the photoreceptive layer as a monolayer.

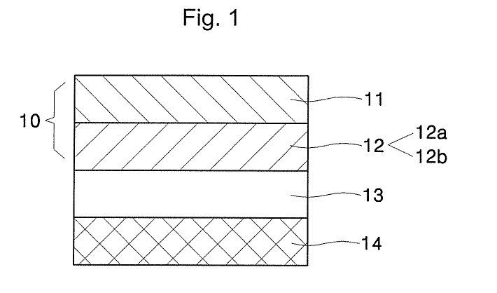

An example of a dye-sensitized solar cell including a photoreceptive layer according to the present invention is illustrated in FIG. 1. Referring to FIG. 1, a solar cell includes a semiconductor electrode 10, an electrolyte layer 13, and an opposite electrode 14. The semiconductor electrode 10 includes a conductive transparent substrate 11 and a photoreceptive layer 12. As described above, the photoreceptive layer 12 includes metal oxide 12a and first and second dyes 12b.

A transparent substrate for the conductive transparent substrate 11 is not particularly limited provided that it has transparency. The transparent substrate may be a glass substrate. A material capable of imparting conductivity to the transparent substrate may be any material having conductivity and transparency. In view of high conductivity, transparency, in particular heat resistance, a fluorine-doped tin oxide (e.g., SnO₂) is preferable. In view of cost-effectiveness, indium-doped tin oxide (ITO) or fluorine-doped tin oxide (FTO) is preferable.

The photoreceptive layer 12 composed of the metal oxide 12a and the first and second dyes 12b has a thickness of 15 microns or less, preferably approximately 5 to 15 microns. Generally, a photoreceptive layer has a high series resistance due to its structural feature, thereby lowering photoelectric conversion efficiency. In this regard, the use of the photoreceptive layer 12 with a thickness of 15 microns or less can reduce a series resistance while maintaining the intrinsic function of the photoreceptive layer 12, thereby preventing a reduction in photoelectric conversion efficiency.

The electrolyte layer 13 is composed of an electrolyte solution. The electrolyte layer 13 may include the photoreceptive layer 12 or may be formed so that the photoreceptive layer 12 is impregnated with the electrolyte solution. The electrolyte solution may be an iodine acetonitrile solution but is not limited thereto. There are no limitations on the electrolyte solution provided that the electrolyte solution has a hole transport function.

The opposite electrode 14 is not limited provided that it is made of a conductive material. However, provided that a conductive layer is formed on an opposite side to the semiconductor electrode 10, the opposite electrode 14 may also be made of an insulating material. It is preferable to use an electrode made of an electrochemically stable material as the opposite electrode 14. Preferably, the opposite electrode 14 may be made of platinum, gold, or carbon. Furthermore, it is preferable that an opposite side to the semiconductor substrate 10 has a microporous structure to increase a surface area for the purpose of enhancing a redox catalytic effect. In this regard, it is preferable that the opposite electrode 14 made of platinum is in a platinum black state and the opposite electrode 14 made of carbon is in a porous state. The platinum black state may be formed by anode oxidation using platinum or platinum chloride acid treatment, and the porous state may be formed by sintering carbon microparticles or an organic polymer.

A method of manufacturing a dye-sensitized solar cell with the above-described structure according to the present invention is not particularly limited and thus may be any method commonly known in the pertinent art.

Hereinafter, the present invention will be described more specifically with reference to the following examples. The following examples are for illustrative purposes and are not intended to limit the scope of the invention.

### Example 1

A titanium dioxide colloid solution was prepared by hydrothermal synthesis using titanium isopropoxide and acetic acid in an autoclave that had been set to 220° C. A solvent was evaporated from the colloid solution until the content of titanium dioxide reached 12 wt % to obtain a colloid solution containing titanium dioxide with a nanoscale particle size (about 5 to 30 nm).

Next, hydroxypropyl cellulose (Mw: 80,000) was added to the resultant colloid solution and stirred for 24 hours to make a titanium dioxide coating slurry. Then, the titanium dioxide coating slurry was coated on a transparent conductive glass substrate coated with indium tin oxide (ITO) and having 80% transmissivity by a doctor blade method and heated at about 450° C. for one hour so that the contact and filling between titanium dioxide nanoparticles except an organic polymer occurred to thereby obtain a conductive transparent substrate structure with a thickness of approximately 10 microns including a titanium dioxide layer with a thickness of approximately 6 microns.

Next, the conductive transparent substrate having thereon the titanium dioxide layer was dipped in a solution containing 0.3 mM ruthenium dithiocyanate 2,2′-bipyridyl-4,4′-dicarboxylate as a first dye for 24 hours and dried to adsorb the first dye onto the conductive transparent substrate.

Next, the resultant conductive transparent substrate was dipped in a solution of a compound of formula 2 below in acetonitrile, washed, and dried:

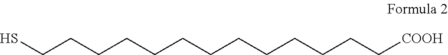

The resultant conductive transparent substrate was dipped in a solution of a CdSe/CdS quantum dot compound as a second dye in acetonitrile, washed, and dried, to thereby manufacture a semiconductor electrode including a photoreceptive layer according to the present invention.

On the other hand, an opposite electrode was manufactured by coating an ITO-doped conductive transparent glass substrate with platinum. Then, the opposite electrode used as an anode and the semiconductor electrode used as a cathode were assembled. At this time, the opposite electrode and the semiconductor electrode were assembled so that conductive surfaces faced each other, i.e., the platinum layer of the opposite electrode and the photoreceptive layer of the semiconductor electrode faced each other. The two electrodes were closely adhered to each other when heated to about 100-140° C. using a heating plate by means of a polymer layer made of SURLYN (manufactured by DuPont) having a thickness of about 40 microns as an intermediate layer between the two electrodes under a pressure of about 1-3 atm. The SURLYN polymer accordingly was adhered to the surfaces of the two electrodes by heat and pressure.

Next, a space defined by the two electrodes was filled with an electrolyte solution through micropores formed on the surface of the opposite electrode to thereby complete a dye-sensitized solar cell according to the present invention. The electrolyte solution was an I₃⁻/I⁻ electrolyte solution obtained by dissolving 0.6M 1,2-dimethyl-3-octyl-imidazolium iodide, 0.2M Lil, 0.04M I₂, and 0.2M 4-tert-butylpyridine (TBP) in acetonitrile.

### Example 2

A dye-sensitized solar cell was manufactured in the same manner as in Example 1 using a compound of formula 3 below instead of the compound of formula 2:

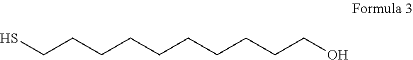

### Example 3

A dye-sensitized solar cell was manufactured in the same manner as in Example 1 using a compound of formula 4 below instead of the compound of formula 2:

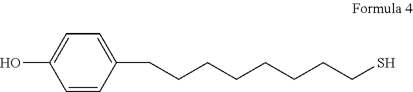

### Example 4

A dye-sensitized solar cell was manufactured in the same manner as in Example 1 using a compound of formula 5 below instead of the compound of formula 2:

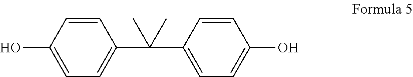

### Example 5

A dye-sensitized solar cell was manufactured in the same manner as in Example 1 using a compound of formula 6 below instead of the compound of formula 2:

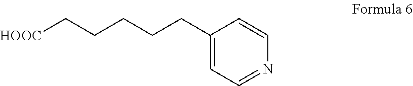

### Example 6

A dye-sensitized solar cell was manufactured in the same manner as in Example 1 using a compound of formula 7 below instead of the compound of formula 2:

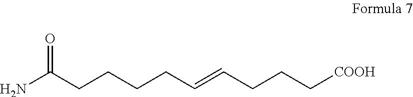

### Example 7

A dye-sensitized solar cell was manufactured in the same manner as in Example 1 using a compound of formula 8 below instead of the compound of formula 2:

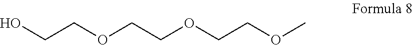

### Example 8

A dye-sensitized solar cell was manufactured in the same manner as in Example 1 using a compound of formula 9 below instead of the compound of formula 2:

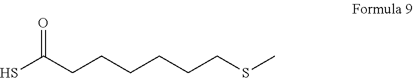

### Comparative Example

A dye-sensitized solar cell was manufactured in the same manner as in Example 1 except that the compound of formula 2 and the second dye were not used.

### Experimental Example 1

To evaluate the photoelectric conversion efficiency of the dye-sensitized solar cells manufactured in Examples 1-8 and Comparative Example, photovoltage and photocurrent of the dye-sensitized solar cells were measured.

A xenon lamp (Oriel, 01193) was used as an optical source. The solar conditions (AM 1.5) of the xenon lamp were corrected using a standard solar cell (Frunhofer Institute Solare Engeriessysteme, Certificate No. C-ISE369, Type of material: Mono-Si+KG filter) to plot a photocurrent-photovoltage curve. The photoelectric conversion efficiency was calculated using the photocurrent-photovoltage curve according to the following equation and the results are presented in Table 1 below.

ηₑ=(V_{oc}I_{sc}FF)/(P_{inc})

ηₑ photoelectric conversion efficiency, I_{sc}=current density, V_{oc}=voltage, FF=fill factor, and P_{inc}=100 mw/cm² (1sun).

TABLE 1

| Section | Photoelectric conversion efficiency (%) |
|---|---|
| Example 1 | 4.7 |
| Example 2 | 4.8 |
| Example 3 | 4.9 |
| Example 4 | 4.6 |
| Example 5 | 4.5 |
| Example 6 | 4.6 |
| Example 7 | 4.8 |
| Example 8 | 4.8 |
| Comparative Example | 3.9 |

From Table 1, it can be seen that in a photoreceptive layer according to the present invention and a dye-sensitized solar cell including the same, the inclusion of a second dye on a surface of metal oxide in addition to a first dye enhances the total fill density of the dyes, and the second dye complementarily absorbs light at a near-infrared wavelength range that cannot be absorbed by the first dye, thereby enhancing total photoelectric conversion efficiency.

A photoreceptive layer according to the present invention includes a secondary dye adsorbed onto a surface of metal oxide via a predetermined compound, in addition to a primary dye, unlike a conventional photoreceptive layer including a single type of dye, which enhances a dye fill density and enables light absorption at a broad wavelength range. Therefore, the photoreceptive layer can be usefully adopted in a dye-sensitized solar cell.

What is claimed is:

1. A photoreceptive layer comprising:
a metal oxide;
a first dye formed on a surface of the metal oxide; and
a second dye comprising a quantum dot compound formed on another surface of the metal oxide via a compound represented by formula 1 below: 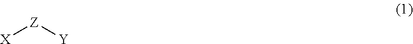
wherein X is a functional group binding with the metal oxide;
Y is a functional group binding with the second dye; and
Z is a bond, a substituted or unsubstituted alkylene group of 1-30 carbon atoms, a substituted or unsubstituted alkenylene group of 2-30 carbon atoms, a substituted or unsubstituted heteroalkylene group of 1-30 carbon atoms, a substituted or unsubstituted heteroalkenylene group of 2-30 carbon atoms, a substituted or unsubstituted arylene group of 6-30 carbon atoms, a substituted or unsubstituted heteroarylene group of 3-30 carbon atoms, or a substituted or unsubstituted arylalkylene group of 6-30 carbon atoms.

2. The photoreceptive layer of claim 1, wherein X and Y are each independently —COOR, —OCOR, —COSR, —SCOR, —NRR′, —OR, or —OSR where R and R′ are each independently a hydrogen atom, a halogen atom, a cyanide group, a nitro group, a substituted or unsubstituted alkyl group of 1-10 carbon atoms, a substituted or unsubstituted alkenyl group of 2-10 carbon atoms, a substituted or unsubstituted alkoxy group of 1-10 carbon atoms, a substituted or unsubstituted aryl group of 6-20 carbon atoms, a substituted or unsubstituted heteroaryl group of 6-20 carbon atoms, a substituted or unsubstituted aryloxy group of 6-20 carbon atoms, or a substituted or unsubstituted heteroaryloxy group of 6-20 carbon atoms.

3. The photoreceptive layer of claim 1, wherein the compound of formula 1 is one of compounds represented by formulae 2 through 9 below:

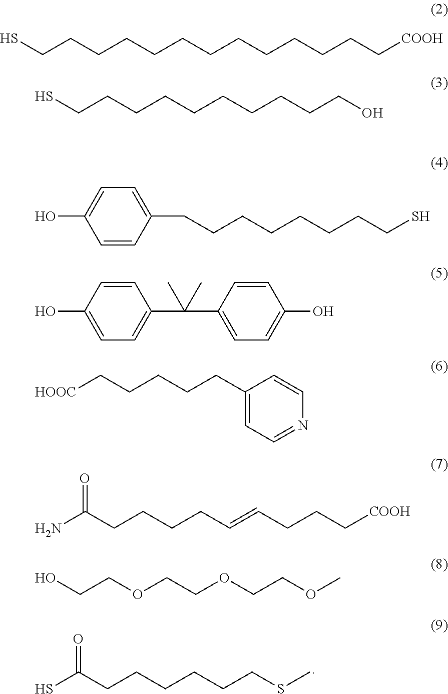

4. The photoreceptive layer of claim 1, wherein the first dye is a ruthenium complex, a xanthine dye, a cyanine dye, phenosafranine, cabri blue, thiosine, a basic dye, a porphyrin compound, an azo dye, a phthalocyanine compound, a ruthenium trisbipyridyl complex, an anthraquinone dye, a polycyclic quinone dye, or a mixture thereof.

5. The photoreceptive layer of claim 1, wherein the quantum dot compound is a material selected from the group consisting of (a) a first element selected from Group II, XII, XIII, and XIV elements and a second element selected from Group XVI elements; (b) a first element selected from Group XIII elements and a second element selected from Group XV elements; and (c) a Group XIV element, or a core-shell structure compound thereof.

6. The photoreceptive layer of claim 1, wherein the quantum dot compound is MgO, MgS, MgSe, MgTe, CaO, CaS, CaSe, CaTe, SrO, SrS, SrSe, SrTe, BaO, BaS, BaSe, BaTE, ZnO, ZnS, ZnSe, ZnTe, CdO, CdS, CdSe, CdTe, HgO, HgS, HgSe, HgTe, Al₂O₃, Al₂S₃, Al₂Se₃, Al₂Te₃, Ga₂O₃, Ga₂S₃, Ga₂Se₃, Ga₂Te₃, In₂O₃, In₂S₃, In₂Se₃, In₂Te₃, SiO₂, GeO₂, SnO₂, SnS, SnSe, SnTe, PbO, PbO₂, PbS, PbSe, PbTe, AlN, AlP, AlAs, AlSb, GaN, GaP, GaAs, GaSb, InN, InP, InAs, InSb, BP, Si, Ge, or a core-shell structure compound thereof.

7. The photoreceptive layer of claim 1, wherein the metal oxide is TiO₂, SnO₂, ZnO, WO₃, Nb₂O₅, TiSrO₃, or a mixture thereof.

8. A method of forming a photoreceptive layer, the method comprising:
adsorbing a first dye on a surface of metal oxide;
spraying a dispersion solution of a compound of formula 1 below in a solvent on the metal oxide on which the first dye is adsorbed or dipping the metal oxide in the dispersion solution, followed by washing and drying; and
coating or dipping the resultant metal oxide with or in a second dye-containing solution, followed by washing and drying: 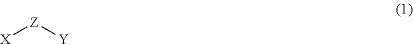
wherein X is a functional group binding with the metal oxide;
Y is a functional group binding with the second dye; and
Z is a bond, a substituted or unsubstituted alkylene group of 1-30 carbon atoms, a substituted or unsubstituted alkenylene group of 2-30 carbon atoms, a substituted or unsubstituted heteroalkylene group of 1-30 carbon atoms, a substituted or unsubstituted heteroalkenylene group of 2-30 carbon atoms, a substituted or unsubstituted arylene group of 6-30 carbon atoms, a substituted or unsubstituted heteroarylene group of 3-30 carbon atoms, or a substituted or unsubstituted arylalkylene group of 6-30 carbon atoms.

9. The method of claim 8, wherein the first dye is a ruthenium complex, a xanthine dye, a cyanine dye, phenosafranine, cabri blue, thiosine, a basic dye, a porphyrin compound, an azo dye, a phthalocyanine compound, a ruthenium trisbipyridyl complex, an anthraquinone dye, a polycyclic quinone dye, or a mixture thereof.

10. A semiconductor electrode comprising:
a conductive transparent substrate; and
the photoreceptive layer of claim 1.

11. The semiconductor electrode of claim 10, wherein a thickness of the photoreceptive layer is in the range from 5 to 15 microns.

12. A dye-sensitized solar cell comprising:
a conductive transparent substrate;
the photoreceptive layer of claim 1;
an electrolyte layer; and
an opposite electrode.

13. The dye-sensitized solar cell of claim 12, wherein a thickness of the photoreceptive layer is in the range from approximately 5 to 15 microns.

14. A semiconductor electrode comprising:
a conductive transparent substrate; and
the photoreceptive layer of claim 2.

15. A semiconductor electrode comprising:
a conductive transparent substrate; and
the photoreceptive layer of claim 3.

16. A semiconductor electrode comprising:
a conductive transparent substrate; and
the photoreceptive layer of claim 4.

17. A dye-sensitized solar cell comprising:
a conductive transparent substrate;
the photoreceptive layer of claim 2;
an electrolyte layer; and
an opposite electrode.

18. A dye-sensitized solar cell comprising:
a conductive transparent substrate;
the photoreceptive layer of claim 3;
an electrolyte layer; and
an opposite electrode.

19. A dye-sensitized solar cell comprising:
a conductive transparent substrate;
the photoreceptive layer of claim 4;
an electrolyte layer; and
an opposite electrode.
